(19) United States
(12) Patent Application Publication
(10) Pub. No.: US 2021/0402550 A1
(43) Pub. Date: Dec. 30, 2021

(54) POLISHING METHOD, POLISHING APPARATUS, AND COMPUTER-READABLE STORAGE MEDIUM STORING PROGRAM

(71) Applicant: EBARA CORPORATION, Tokyo (JP)

(72) Inventors: Yoichi Shiokawa, Tokyo (JP); Keita Yagi, Tokyo (JP); Yuki Watanabe, Tokyo (JP); Nachiketa Chauhan, Tokyo (JP)

(21) Appl. No.: 17/340,548

(22) Filed: Jun. 7, 2021

(30) Foreign Application Priority Data
Jun. 29, 2020 (JP) 2020-111199

(51) Int. Cl. B24B 37/013

(52) U.S. Cl. CPC B24B 37/013

(57) ABSTRACT

A polishing method capable of measuring a film thickness of a substrate, such as a semiconductor wafer, having various structural elements on its surface with high accuracy is disclosed. The polishing method includes: generating spectra of reflected lights from measurement points on a substrate; classifying the spectra based on a shape of each spectrum into primary spectra belonging to a first group and a secondary spectrum belonging to a second group; determining film thicknesses of the substrate from the primary spectra; and determining a film thickness at a measurement point corresponding to the secondary spectrum using the primary spectra or the film thicknesses.

### CROSS REFERENCE TO RELATED APPLICATION

This document claims priority to Japanese Patent Application No. 2020-111199 filed Jun. 29, 2020, the entire contents of which are hereby incorporated by reference.

### BACKGROUND

A polishing apparatus for polishing a substrate, such as a semiconductor wafer, is configured to polish the surface of the substrate by pressing the substrate against a polishing pad on a polishing table while rotating the substrate and the polishing pad by a polishing head and the polishing table, respectively. A CMP (Chemical Mechanical Polishing) apparatus, which is a typical example of the polishing apparatus, is configured to press a substrate against a polishing pad in the presence of slurry while supplying the slurry onto the polishing pad. The surface of the substrate is polished by the chemical action of the slurry and the mechanical action of abrasive grains contained in the slurry.

In such a polishing apparatus, an in-situ type spectroscopic film-thickness measuring apparatus is used for the purpose of detecting a film thickness of a dielectric layer (a transparent layer) of the substrate. This spectroscopic film-thickness measuring apparatus includes a light source and a spectrometer mounted to the polishing table, and further includes a light-emitting optical fiber cable and a light-receiving optical fiber cable coupled to the light source and the spectrometer, respectively. The distal ends of these optical fiber cables serve as an optical sensor head.

The optical sensor head scans the substrate surface each time the polishing table makes one rotation. Specifically, the optical sensor head irradiates multiple measurement points on the substrate with light while sweeping across the substrate, and receives the reflected lights from these measurement points. The spectrometer decomposes each reflected light from each measurement point according to wavelength and generates light intensity data. A spectrum generator of the spectroscopic film-thickness measuring apparatus generates a spectrum of the reflected light from the light intensity data. Since this spectrum changes according to a film thickness of the substrate, the spectroscopic film-thickness measuring apparatus can determine a current film thickness of the substrate based on the spectrum.

However, in such an in-situ type spectroscopic film-thickness measuring apparatus, the film thickness of the rotating substrate is measured while the optical sensor head is moving. Therefore, positions of the measurement points on the substrate are not fixed. The surface of the substrate is composed of various structural elements, such as devices and scribe lines. The intensity of the reflected light from the substrate can vary depending not only on the film thickness, but also on these structural elements constituting the surface of the substrate. For example, an intensity of reflected light from a device is different from an intensity of reflected light from a scribe line. In other example, an intensity of reflected light may vary due to a difference in structure underlying a device. As a result, the film-thickness measurement results can vary from measurement point to measurement point.

### SUMMARY OF THE INVENTION

Therefore, there are provided a polishing method and a polishing apparatus capable of measuring a film thickness of a substrate, such as a semiconductor wafer, having various structural elements on its surface with high accuracy.

Embodiments, which will be described below, relate to a method and an apparatus for polishing a substrate, such as a wafer, and more particularly to a technique of detecting a film thickness based on optical information contained in reflected light from the substrate.

In an embodiment, there is provided a polishing method comprising: generating spectra of reflected lights from measurement points on a substrate while polishing the substrate; classifying the spectra based on a shape of each spectrum into primary spectra belonging to a first group and a secondary spectrum belonging to a second group; determining film thicknesses of the substrate from the primary spectra; and determining a film thickness at a measurement point corresponding to the secondary spectrum using the primary spectra or the film thicknesses.

In an embodiment, determining the film thickness at the measurement point corresponding to the secondary spectrum comprises: generating an estimated spectrum that corresponds to the secondary spectrum and belongs to the first group; and determining the film thickness of the substrate from the estimated spectrum.

In an embodiment, generating the estimated spectrum comprises generating the estimated spectrum by interpolation or extrapolation using the primary spectra.

In an embodiment, generating the estimated spectrum comprises inputting the primary spectra into a spectrum generating model and outputting the estimated spectrum from the spectrum generating model.

In an embodiment, determining the film thickness at the measurement point corresponding to the secondary spectrum comprises determining the film thickness at the measurement point corresponding to the secondary spectrum by interpolation or extrapolation using the film thicknesses.

In an embodiment, classifying the spectra into the primary spectra belonging to the first group and the secondary spectrum belonging to the second group comprises:

inputting each of the spectra generated during polishing of the substrate into a classification model; and classifying the spectra into the primary spectra belonging to the first group and the secondary spectrum belonging to the second group according to classification results output from the classification model.

In an embodiment, the polishing method further comprises: generating multiple training spectra of reflected lights from a sample substrate while polishing the sample substrate; classifying the multiple training spectra into the first group and the second group; and determining parameters of the classification model by machine learning using classification training data including the multiple training spectra and classification results of the multiple training spectra.

In an embodiment, there is provided a polishing method comprising: generating spectra of reflected lights from measurement points on a reference substrate while polishing the reference substrate; classifying the spectra based on a shape of each spectrum into primary spectra belonging to a first group and a secondary spectrum belonging to a second group; generating an estimated spectrum that corresponds to the secondary spectrum and belongs to the first group; associating the primary spectra and the estimated spectra with film thicknesses; adding the primary spectra and the estimated spectrum as reference spectra to a database, the database having reference spectra including the primary spectra and the estimated spectrum; generating a spectrum of reflected light from a substrate, while polishing the substrate; determining a reference spectrum having the closest shape to the shape of the spectrum of the reflected light from the substrate; and determining a film thickness associated with the determined reference spectrum.

In an embodiment, there is provided a polishing apparatus comprising: a polishing table for supporting polishing pad; a polishing head configured to press a substrate against the polishing pad to polish the substrate; an optical sensor head configured to emit light to measurement points on the substrate and receive reflected lights from the measurement points; and a processing system configured to generate spectra of the reflected lights, the processing system being configured to: classify the spectra based on a shape of each spectrum into primary spectra belonging to a first group and a secondary spectrum belonging to a second group; determine film thicknesses of the substrate from the primary spectra; and determine a film thickness at a measurement point corresponding to the secondary spectrum using the primary spectra or the film thicknesses.

In an embodiment, the processing system is configured to: generate an estimated spectrum that corresponds to the secondary spectrum and belongs to the first group; and determine the film thickness of the substrate from the estimated spectrum.

In an embodiment, the processing system is configured to generate the estimated spectrum by interpolation or extrapolation using the primary spectra.

In an embodiment, the processing system has a spectrum generating model, and the processing system is configured to input the primary spectra into the spectrum generating model and output the estimated spectrum from the spectrum generating model.

In an embodiment, the processing system is configured to determine the film thickness at the measurement point corresponding to the secondary spectrum by interpolation or extrapolation using the film thicknesses.

In an embodiment, the processing system has a classification model, and the processing system is configured to: input each of the spectra generated during polishing of the substrate into the classification model; and classify the spectra into the primary spectra belonging to the first group and the secondary spectrum belonging to the second group according to classification results output from the classification model.

In an embodiment, the processing system has a memory storing multiple training spectra of reflected lights from a sample substrate, and the processing system is configured to: classify the multiple training spectra into the first group and the second group; and determine parameters of the classification model by machine learning using classification training data including the multiple training spectra and classification results of the multiple training spectra.

In an embodiment, there is provided a polishing apparatus comprising: a polishing table for supporting polishing pad; a polishing head configured to press a substrate against the polishing pad to polish the substrate; an optical sensor head configured to emit light to measurement points on the substrate and receive reflected lights from the measurement points; and a processing system having a memory storing a database and spectra of reflected lights from measurement points on a reference substrate, the database containing reference spectra, the processing system being configured to: classify the spectra of the reflected lights based on a shape of each spectrum into primary spectra belonging to a first group and a secondary spectrum belonging to a second group; generate an estimated spectrum that corresponds to the secondary spectrum and belongs to the first group; associate the primary spectra and the estimated spectra with film thicknesses; and add the primary spectra and the estimated spectrum as reference spectra to the database.

In an embodiment, there is provided a computer-readable storage medium storing a program, the program being configured to cause a computer to: generate spectra of reflected lights from measurement points on a substrate during polishing of the substrate; classify the spectra based on a shape of each spectrum into primary spectra belonging to a first group and a secondary spectrum belonging to a second group; determine film thicknesses of the substrate from the primary spectra; and determine a film thickness at a measurement point corresponding to the secondary spectrum using the primary spectra or the film thicknesses.

In an embodiment, determining the film thickness at the measurement point corresponding to the secondary spectrum comprises: generating an estimated spectrum that corresponds to the secondary spectrum and belongs to the first group; and determining the film thickness of the substrate from the estimated spectrum.

In an embodiment, generating the estimated spectrum comprises generating the estimated spectrum by interpolation or extrapolation using the primary spectra.

In an embodiment, generating the estimated spectrum comprises inputting the primary spectra into a spectrum generating model and outputting the estimated spectrum from the spectrum generating model.

In an embodiment, determining the film thickness at the measurement point corresponding to the secondary spectrum comprises determining the film thickness at the measurement point corresponding to the secondary spectrum by interpolation or extrapolation using the film thicknesses.

In an embodiment, classifying the spectra into the primary spectra belonging to the first group and the secondary spectrum belonging to the second group comprises: inputting each of the spectra generated during polishing of the substrate into a classification model; and classifying the spectra into the primary spectra belonging to the first group and the secondary spectrum belonging to the second group according to classification results output from the classification model.

In an embodiment, the program is further configured to cause the computer to: generate multiple training spectra of reflected lights from a sample substrate during polishing of the sample substrate; classify the multiple training spectra into the first group and the second group; and determine parameters of the classification model by machine learning using classification training data including the multiple training spectra and classification results of the multiple training spectra.

In an embodiment, there is provided a computer-readable storage medium storing a program, the program being configured to cause a computer to: generate spectra of reflected lights from measurement points on a reference substrate during polishing of the reference substrate; classify the spectra based on a shape of each spectrum into primary spectra belonging to a first group and a secondary spectrum belonging to a second group; generate an estimated spectrum that corresponds to the secondary spectrum and belongs to the first group; associate the primary spectra and the estimated spectra with film thicknesses; add the primary spectra and the estimated spectrum as reference spectra to a database, the database having reference spectra including the primary spectra and the estimated spectrum; generate a spectrum of reflected light from a substrate during polishing of the substrate; determine a reference spectrum having the closest shape to the shape of the spectrum of the reflected light from the substrate; and determine a film thickness associated with the determined reference spectrum.

The estimated spectrum is a primary spectrum that is assumed to accurately reflect the film thickness of the substrate. Therefore, the processing system can determine an accurate film thickness of the substrate from the estimated spectrum. In particular, the processing system can determine an accurate film thickness at all the multiple measurement points on the substrate.

### BRIEF DESCRIPTION OF THE DRAWINGS

FIG. 1 is a schematic view showing an embodiment of a polishing apparatus;

FIG. 2 is a diagram showing an example of a spectrum generated by a processing system;

FIGS. 3A to 3C are schematic views each showing an example of the processing system;

FIG. 4 is a cross-sectional view showing an embodiment of a detailed configuration of the polishing apparatus shown in FIG. 1;

FIG. 5 is a schematic diagram illustrating a principle of an optical film-thickness measuring device;

FIG. 6 is a plan view showing a positional relationship between substrate and polishing table;

FIG. 7 is a diagram illustrating an example of a method of determining a film thickness from a spectrum of reflected light;

FIG. 8 is a schematic diagram showing an example of multiple measurement points on a surface (i.e., a surface to be polished) of a substrate;

FIG. 9 is a diagram illustrating an embodiment in which an estimated spectrum is generated from primary spectra at adjacent measurement points;

FIG. 10 is a diagram illustrating an embodiment in which an estimated spectrum is generated from time-series primary spectra along a polishing time;

FIG. 11 is a flowchart illustrating operations of the optical film-thickness measuring device when determining a film thickness of a substrate;

FIG. 12 is a schematic diagram showing an example of a spectrum generating model;

FIG. 13 is a flowchart showing an embodiment of updating a database of reference spectra;

FIG. 14 is a flowchart for explaining automatic classification of spectra and generating of a classification model constituting a spectrum classification method;

FIG. 15 is a schematic diagram showing an example of the classification model; and

FIG. 16 is a flowchart illustrating operations of the optical film-thickness measuring device having the classification model when determining a film thickness of a substrate.

### DESCRIPTION OF EMBODIMENTS

Embodiments will be described below with reference to the drawings.

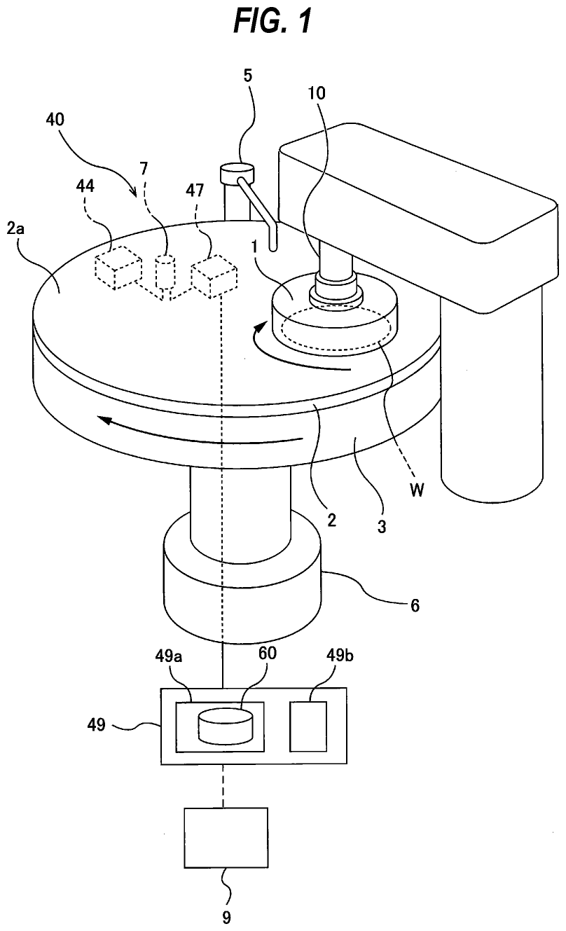

FIG. 1 is schematic view showing an embodiment of a polishing apparatus. As shown in FIG. 1, the polishing apparatus includes a polishing table 3 for supporting a polishing pad 2, a polishing head 1 configured to press a substrate W (e.g., a wafer) having a film against the polishing pad 2, a table motor 6 configured to rotate the polishing table 3, and a polishing-liquid supply nozzle 5 arranged to supply a polishing liquid (e.g., slurry) onto the polishing pad 2. The polishing pad 2 has an upper surface constituting a polishing surface 2a for polishing the substrate W.

The polishing head 1 is coupled to a head shaft 10, which is coupled to a polishing-head motor (now shown). The polishing-head motor is configured to rotate the polishing head 1 together with the head shaft 10 in a direction indicated by an arrow. The polishing table 3 is coupled to the table motor 6, which is configured to rotate the polishing table 3 and the polishing pad 2 in a direction indicated by an arrow.

Polishing of the substrate W is performed as follows. The polishing-liquid supply nozzle 5 supplies the polishing liquid onto the polishing surface 2a of the polishing pad 2 on the polishing table 3, while the polishing table 3 and the polishing head 1 are rotated in directions indicated by the arrows in FIG. 1. While the substrate W is being rotated by the polishing head 1, the substrate W is pressed by the polishing head 1 against the polishing surface 2a of the polishing pad 2 in the presence of the polishing liquid on the polishing pad 2. The surface of the substrate W is polished by a chemical action of the polishing liquid and a mechanical action of abrasive grains contained in the polishing liquid.

The polishing apparatus includes an optical film-thickness measuring device 40 configured to determine a film thickness of the substrate W. The optical film-thickness measuring device 40 includes a light source 44 for emitting light, a spectrometer 47, an optical sensor head 7 coupled to the light source 44 and the spectrometer 47, and a processing system 49 coupled to the spectrometer 47. The optical sensor head 7, the light source 44, and the spectrometer 47 are secured to the polishing table 3, and rotate together with the polishing table 3 and the polishing pad 2. The position of the optical sensor head 7 is such that the optical sensor head 7 sweeps across the surface of the substrate W on the polishing pad 2 each time the polishing table 3 and the polishing pad 2 make one rotation.

The processing system 49 includes a memory 49a storing programs therein for generating a spectrum and determining a film thickness of the substrate W, which will be described later, and a processor 49b for performing arithmetic operations according to instructions included in the programs. The processing system 49 is composed of at least one computer. The memory 49a includes a main memory, such as random access memory (RAM), and an auxiliary memory, such as a hard disk drive (HDD) or a solid state drive (SSD). Examples of the processor 49b include a CPU (central processing unit) and a GPU (graphic processing unit). However, the specific configurations of the processing system 49 are not limited to these examples.

The light emitted by the light source 44 is transmitted to the optical sensor head 7, which directs the light to the surface of the substrate W. The light is reflected off the surface of the substrate W, and the reflected light from the substrate W is received by the optical sensor head 7 and is further transmitted to the spectrometer 47. The spectrometer 47 decomposes the reflected light according to wavelength, and measures an intensity of the reflected light at each of wavelengths. The intensity measurement data of the reflected light is transmitted to the processing system 49.

The processing system 49 is configured to produce a spectrum of the reflected light from the intensity measurement data of the reflected light. This spectrum of the reflected light is expressed as a line graph (i.e., a spectral waveform) indicating a relationship between the wavelength and the intensity of the reflected light. The intensity of the reflected light can also be represented by a relative value, such as a reflectance or a relative reflectance.

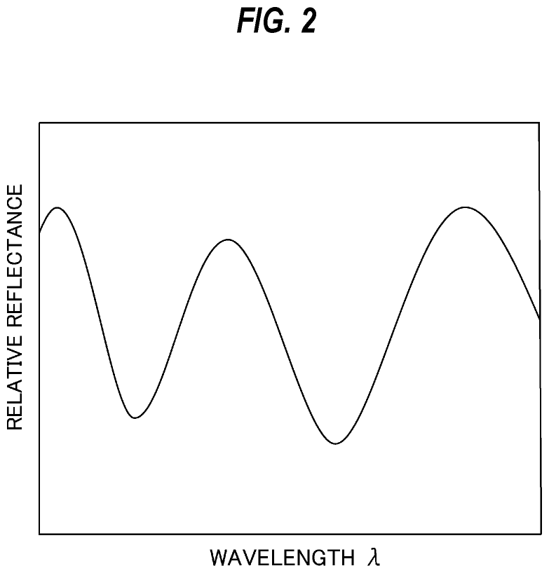

FIG. 2 is a diagram showing an example of a spectrum generated by the processing system 49. The spectrum is represented as a line graph (i.e., a spectral waveform) showing the relationship between the wavelength and intensity of light. In FIG. 2, horizontal axis represents wavelength of the light reflected from the substrate, and vertical axis represents relative reflectance derived from the intensity of the reflected light. The relative reflectance is an index value that represents the intensity of the reflected light. Specifically, the relative reflectance is a ratio of the intensity of the light to a predetermined reference intensity. By dividing the intensity of the light (i.e., the actually measured intensity) at each wavelength by a predetermined reference intensity, unwanted noises, such as a variation in the intensity inherent in an optical system or the light source of the apparatus, are removed from the actually measured intensity.

The reference intensity is an intensity that has been measured in advance at each of the wavelengths. The relative reflectance is calculated at each of the wavelengths. Specifically, the relative reflectance is determined by dividing the intensity of the light (the actually measured intensity) at each wavelength by the corresponding reference intensity. The reference intensity is, for example, obtained by directly measuring the intensity of light emitted from the optical sensor head 7, or by irradiating a mirror with light from the optical sensor head 7 and measuring the intensity of reflected light from the mirror. Alternatively, the reference intensity may be an intensity of the reflected light which is measured by the spectrometer 47 when a silicon substrate (bare substrate) with no film thereon is being water-polished in the presence of water on the polishing pad 2, or when the silicon substrate (bare substrate) is placed on the polishing pad 2.

In the actual polishing process, a dark level (which is a background intensity obtained under the condition that light is cut off) is subtracted from the actually measured intensity to determine a corrected actually measured intensity. Further, the dark level is subtracted from the reference intensity to determine a corrected reference intensity. Then the relative reflectance is calculated by dividing the corrected actually measured intensity by the corrected reference intensity. Specifically, the relative reflectance R(λ) can be calculated by using the following formula (1)

$$R ( λ ) = \frac{E ( λ ) - D ( λ )}{B ( λ ) - D ( λ )} \qquad ( 1 )$$

where λ is wavelength, E(λ) is the intensity of the light reflected from the wafer at the wavelength λ, B(λ) is the reference intensity at the wavelength λ, and D(λ) is the background intensity (i.e., dark level) at the wavelength λ obtained under the condition that light is cut off.

Each time the polishing table 3 makes one rotation, the optical sensor head 7 directs the light to the surface (i.e., the surface to be polished) of the substrate W and receives the reflected light from the substrate W. The reflected light is transmitted to the spectrometer 47. The spectrometer 47 decomposes the reflected light according to wavelength and measures the intensity of the reflected light at each of wavelengths. The intensity measurement data of the reflected light is sent to the processing system 49, which produces a spectrum, as shown in FIG. 2, from the intensity measurement data of the reflected light. Further, the processing system 49 determines a film thickness of the substrate W from the spectrum of the reflected light. In the example shown in FIG. 2, the spectrum of the reflected light is a spectral waveform showing the relationship between the relative reflectance and the wavelength of the reflected light. The spectrum of the reflected light may be a spectral waveform showing a relationship between the intensity itself of the reflected light and the wavelength of the reflected light.

As shown in FIG. 1, the memory 49a of the processing system 49 has a database 60 containing data of a plurality of reference spectra. The plurality of reference spectra are spectra of reflected lights from a plurality of substrates that have been polished previously, in other words, spectra of reflected lights produced when substrates, other than the substrate W, were polished. In the following descriptions, a substrate used to produce a reference spectrum is referred to as a reference substrate.

The processing system 49 is composed of at least one computer. The at least one computer may be one server or a plurality of servers. The processing system 49 may be an edge server coupled to the spectrometer 47 by a communication line, or may be a cloud server or a fog server coupled to the spectrometer 47 by a communication network, such as the Internet or a local area network. The processing system 49 may be a fog computing device (e.g., a gateway, a fog server, or a router) arranged in a network coupled to the spectrometer 47.

The processing system 49 may be a plurality of servers coupled by a communication network, such as the Internet or a local area network. For example, the processing system 49 may be a combination of an edge server and a cloud server. In one embodiment, the database 60 may be provided in a data server (not shown) located away from the processor 49b.

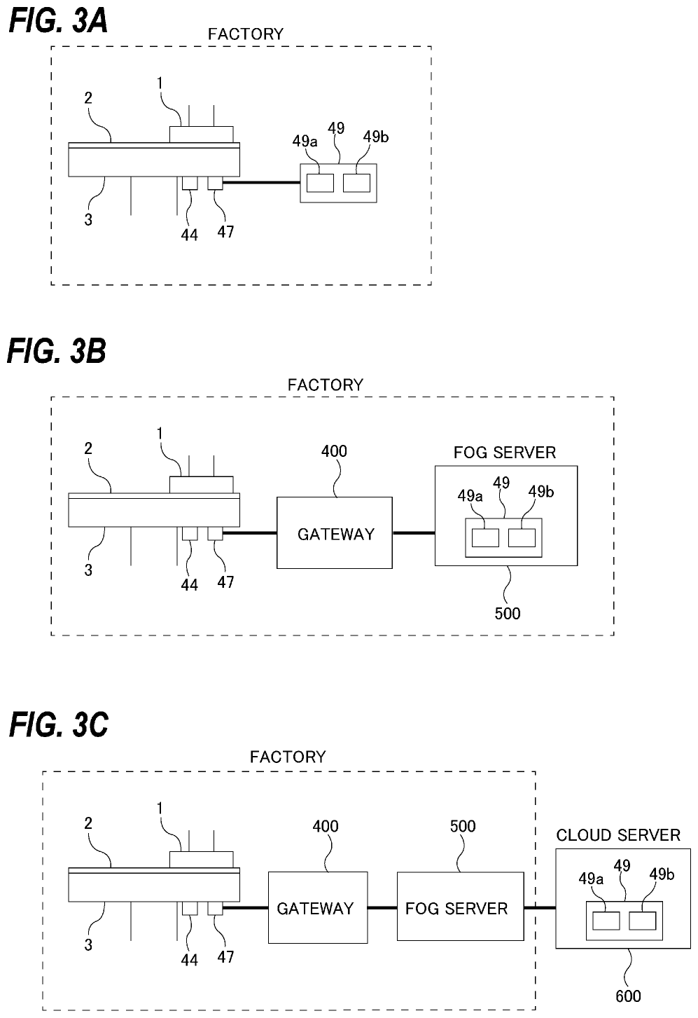

FIGS. 3A to 3C are schematic diagrams each showing an example of the processing system 49. FIG. 3A shows an example in which the entire processing system 49 is provided as a controller arranged in a factory where the polishing table 3 and the polishing head 1 are installed. In this example, the processing system 49 constitutes one apparatus together with the polishing table 3 and the polishing head 1.

FIG. 3B shows an example in which the processing system 49 is provided in a fog server 500 disposed in a factory. The fog server 500 is coupled to the spectrometer 47 through a gateway 400. An example of the gateway 400 is a communication connecting device, such as a router. The gateway 400 may be coupled to the spectrometer 47 and/or the fog server 500 by wire, or may be wirelessly coupled to the spectrometer 47 and/or the fog server 500. In one embodiment, the processing system 49 may be provided within the gateway 400. The embodiment in which the processing system 49 is provided in the gateway 400 is suitable for high-speed processing of the intensity measurement data of the reflected light sent from the spectrometer 47. On the other hand, the embodiment in which the processing system 49 is provided in the fog server 500 may be used when high-speed processing is not required. In one embodiment, a plurality of computers constituting the processing system 49 may be provided in both the gateway 400 and the fog server 500.

FIG. 3C shows an example in which the processing system 49 is provided in a cloud server 600 provided outside the factory. The cloud server 600 is coupled to the spectrometer 47 via a fog server 500 and a gateway 400. The fog server 500 may be omitted. The embodiment shown in FIG. 3C is suitable when a plurality of polishing apparatuses are coupled to the cloud server 600 by a communication network and the processing system 49 processes a large amount of data.

Returning back to FIG. 1, the processing system 49 is coupled to a polishing controller 9 for controlling polishing operation for the substrate W. The polishing controller 9 is configured to control the polishing operation for the substrate W based on the film thickness of the substrate W determined by the processing system 49. For example, the polishing controller 9 is configured to determine a polishing end point at which the film thickness of the substrate W reaches a target film thickness, or change polishing conditions of the substrate W when the film thickness of the substrate W reaches a predetermined value.

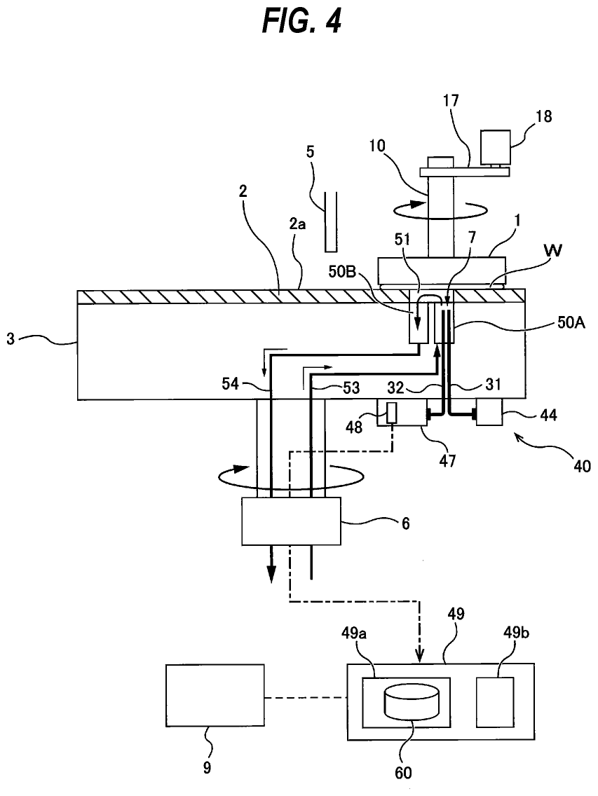

FIG. 4 is a cross-sectional view showing an embodiment of detailed configurations of the polishing apparatus shown in FIG. 1. The head shaft 10 is coupled to a polishing-head motor 18 via a coupling device 17, such as belt, so that the head shaft 10 is rotated by the polishing-head motor 18. This rotation of the head shaft 10 is transmitted to the polishing head 1 to rotate the polishing head 1 in the direction indicated by the arrow.

The spectrometer 47 includes a light detector 48. In one embodiment, the light detector 48 may be constituted by photodiode, CCD, or CMOS. The optical sensor head 7 is optically coupled to the light source 44 and the light detector 48. The light detector 48 is electrically coupled to the processing system 49.

The optical film-thickness measuring device 40 further includes a light-emitting optical fiber cable 31 arranged to direct the light, emitted by the light source 44, to the surface of the substrate W, and a light-receiving optical fiber cable 32 arranged to receive the reflected light from the substrate W and transmit the reflected light to the spectrometer 47. A distal end of the light-emitting optical fiber cable 31 and a distal end of the light-receiving optical fiber cable 32 are located in the polishing table 3.

The distal end of the light-emitting optical fiber cable 31 and the distal end of the light-receiving optical fiber cable 32 constitute the optical sensor head 7 that directs the light to the surface of the substrate W and receives the reflected light from the substrate W. The other end of the light-emitting optical fiber cable 31 is coupled to the light source 44, and the other end of the light-receiving optical fiber cable 32 is coupled to the spectrometer 47. The spectrometer 47 is configured to decompose the reflected light from the substrate W according to wavelength and measure intensities of the reflected light over a predetermined wavelength range.

The light source 44 transmits the light to the optical sensor head 7 through the light-emitting optical fiber cable 31, and the optical sensor head 7 emits the light to the substrate W. The reflected light from the substrate W is received by the optical sensor head 7 and transmitted to the spectrometer 47 through the light-receiving optical fiber cable 32. The spectrometer 47 decomposes the reflected light according to its wavelength and measures the intensity of the reflected light at each of the wavelengths. The spectrometer 47 sends the intensity measurement data of the reflected light to the processing system 49. The processing system 49 produces the spectrum of the reflected light from the intensity measurement data of the reflected light.

The polishing table 3 has a first hole 50A and a second hole 50B which open in an upper surface of the polishing table 3. The polishing pad 2 has a through-hole 51 at a position corresponding to the holes 50A and 50B. The holes 50A and 50B are in fluid communication with the through-hole 51, which opens in the polishing surface 2a. The first hole 50A is coupled to a liquid supply line 53. The second hole 50B is coupled to a drain line 54. The optical sensor head 7, composed of the end of the light-emitting optical fiber cable 31 and the end of the light-receiving optical fiber cable 32, is located in the first hole 50A, and is located below the through-hole 51.

During the polishing of the substrate W, pure water as a rinsing liquid is supplied into the first hole 50A through the liquid supply line 53, and further supplied into the through-hole 51 through the first hole 50A. The pure water fills a space between the surface (i.e., the surface to be polished) of the substrate W and the optical sensor head 7. The pure water flows into the second hole 50B and is discharged through the drain line 54. The pure water flowing in the first hole 50A and the through-hole 51 prevents the polishing liquid from entering the first hole 50A, thereby ensuring an optical path.

The light-emitting optical fiber cable 31 is an optical transmission element for transmitting the light, emitted by the light source 44, to the surface of the substrate W. The distal ends of the light-emitting optical fiber cable 31 and the light-receiving optical fiber cable 32 lie in the first hole 50A, and are located near the surface, to be polished, of the substrate W. The optical sensor head 7, composed of the distal end of the light-emitting optical fiber cable 31 and the distal end of the light-receiving optical fiber cable 32, is arranged so as to face the substrate W held by the polishing head 1, so that the surface (i.e., the surface to be polished) of the substrate W is irradiated with the light each time the polishing table 3 makes one revolution. Only one optical sensor head 7 is provided in the polishing table 3 in this embodiment, while a plurality of optical sensor heads 7 may be provided in the polishing table 3.

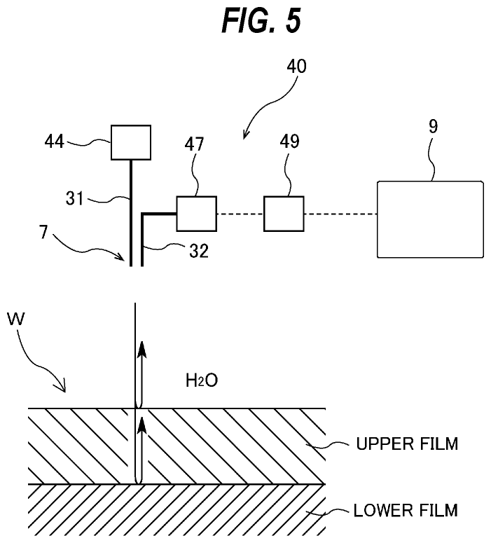

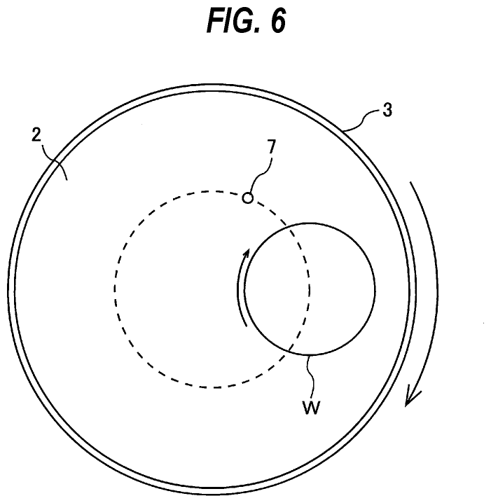

FIG. 5 is a schematic view illustrating the principle of the optical film-thickness measuring device 40, and FIG. 6 is a plan view showing a positional relationship between the substrate W and the polishing table 3. In this example shown in FIG. 5, the substrate W has a lower film and an upper film formed on the lower film. The upper film is, for example, a silicon layer or a dielectric film. The optical sensor heard 7, which is composed of the distal ends of the light-emitting optical fiber cable 31 and the light-receiving optical fiber cable 32, is oriented toward the surface of the substrate W. The optical sensor heard 7 is arranged so as to direct the light to the surface of the substrate W each time the polishing table 3 makes one revolution.

The light, which is cast on the substrate W, is reflected off an interface between a medium (e.g., water in the example of FIG. 5) and the upper film and an interface between the upper film and the lower film. Light waves from these interfaces interfere with each other. The manner of interference between the light waves varies according to the thickness of the upper film (i.e., a length of an optical path). As a result, the spectrum, produced from the reflected light from the substrate, varies according to the thickness of the upper film.

During polishing of the substrate W, each time the polishing table 3 makes one revolution, the optical sensor head 7 sweeps across the substrate W. While the optical sensor head 7 is located below the substrate W, the light source 44 emits the light. The light is directed to the surface (i.e., the surface to be polished) of the substrate W and the reflected light from the substrate W is received by the optical sensor head 7 and is transmitted to the spectrometer 47. The spectrometer 47 measures the intensity of the reflected light at each of the wavelengths over the predetermined wavelength range and sends the intensity measurement data of the reflected light to the processing system 49. The processing system 49 produces a spectrum of the reflected light showing the light intensities at the respective wavelengths from the intensity measurement data.

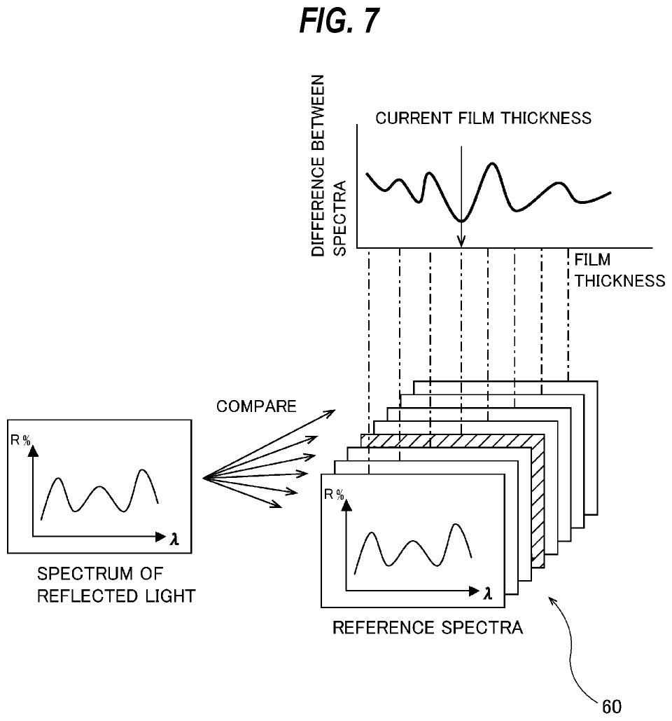

As shown in FIG. 7, the processing system 49 compares the spectrum of the reflected light with a plurality of reference spectra in the database 60, and determines one reference spectrum whose shape is most similar to the spectrum of the reflected light. Specifically, the processing system 49 calculates a difference between the spectrum of the reflected light and each of the reference spectra, and determines a reference spectrum with the smallest calculated difference. The processing system 49 then determines a film thickness associated with the determined reference spectrum.

Each one of the reference spectra is associated with a film thickness in advance when that reference spectrum was obtained. Specifically, the plurality of reference spectra were obtained at different film thicknesses, and these reference spectra correspond to the different film thicknesses. Therefore, a current film thickness of a substrate being polished can be determined by identifying a reference spectrum having a shape closest to the spectrum of reflected light.

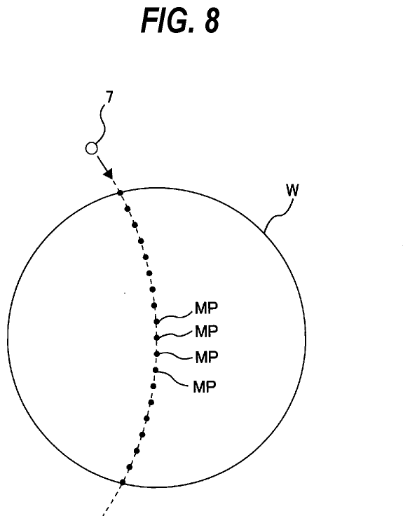

In the present embodiment, each time the optical sensor head 7 is moving across the substrate W, the optical sensor head 7 emits the light successively to multiple measurement points on the substrate W and receives reflected lights from these multiple measurement points. FIG. 8 is a schematic view showing an example of the multiple measurement points on the surface (surface to be polished) of the substrate W. As shown in FIG. 8, each time the optical sensor head 7 sweeps across the substrate W, the optical sensor head 7 directs the light to multiple measurement points MP and receives the reflected lights from the multiple measurement points MP. Therefore, the processing system 49 generates a plurality of spectra corresponding to the reflected lights from the multiple measurement points MP each time the optical sensor head 7 moves across the substrate W (i.e., in each rotation of the polishing table 3). The generated spectra are stored in the memory 49a.

The spectrum of the reflected light can vary depending not only on the film thickness of the substrate W but also on the structural elements (for example, devices, scribe lines, etc.) constituting the surface of the substrate W. Therefore, in the present embodiment, in order to improve the accuracy of the film-thickness measurement of the substrate W, the optical film-thickness measuring device 40 determines the film thickness of the substrate W as follows.

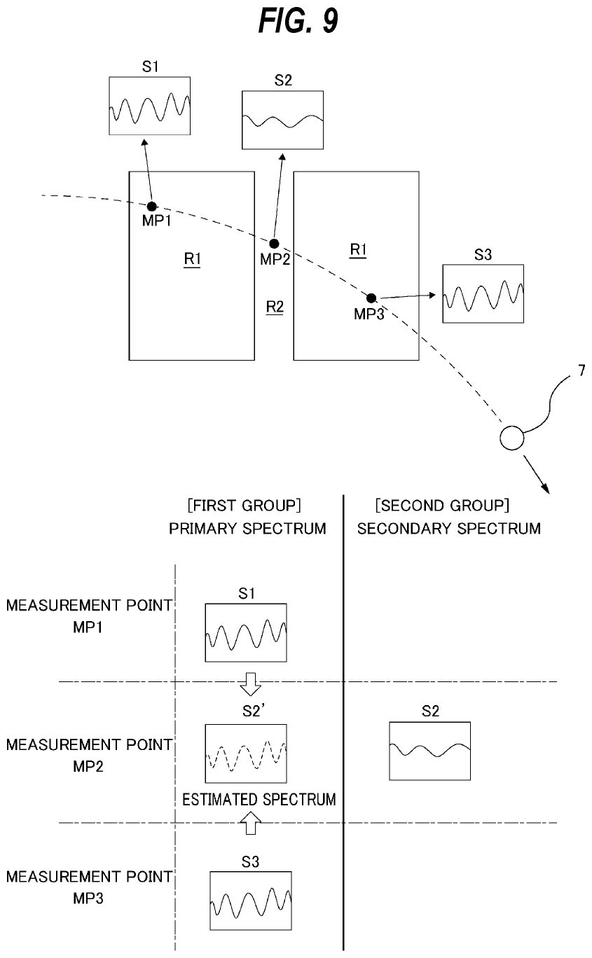

FIG. 9 is a schematic diagram showing an example of spectra of the reflected lights from the multiple measurement points on the substrate W. In the example shown in FIG. 9, a first measurement point MP1 and a third measurement point MP3 are located on first structural elements R1 (for example, devices) of the substrate W, and a second measurement point MP2 is located on a second structural element R2 (for example, a scribe line) of the substrate W. The first structural elements R1 and the second structural element R2 have different surface structures. Due to such a difference in surface structure, the shapes of spectra S1 and S3 of reflected lights from the first measurement point MP1 and the third measurement point MP3 are greatly different from the shape of a spectrum S2 of the reflected light from the second measurement point MP2.

The processing system 49 classifies these spectra S1, S2, and S3 into a primary spectrum belonging to a first group and a secondary spectrum belonging to a second group based on the shapes of the spectra S1, S2, and S3. In the example shown in FIG. 9, the processing system 49 classifies the spectra S1 and S3 of the reflected lights from the first measurement point MP1 and the third measurement point MP3 into the primary spectra belonging to the first group, and classifies the spectrum S2 of the reflected light from the measurement point MP2 into the secondary spectrum belonging to the second group.

The processing system 49 uses the primary spectra S1 and S3 in preference to the secondary spectrum S2 to determine the film thickness of the substrate W. The processing system 49 determines film thicknesses at the first measurement points MP1 and the third measurement point MP3 from the primary spectra S1 and S3 which are the spectra of the reflected lights from the first measurement point MP1 and the third measurement point MP3. The determination of each film thickness is performed according to the processes described with reference to FIG. 7.

Since the secondary spectrum S2 belonging to the second group has a shape significantly different from shapes of the primary spectra S1 and S3 belonging to the first group, a film thickness determined from the secondary spectrum S2 can be relatively inaccurate. Therefore, the processing system 49 determines a film thickness at the second measurement point MP2 as follows.

As shown in FIG. 9, the processing system 49 generates, from the primary spectra S1 and S3, an estimated spectrum S2′ corresponding to the secondary spectrum S2 and belonging to the first group. More specifically, the processing system 49 generates the estimated spectrum S2′ at the second measurement point MP2 by interpolation using the primary spectra S1 and S3 at the first measurement point MP1 and the third measurement point MP3.

The estimated spectrum S2′ has a shape that is to be classified as a primary spectrum belonging to the first group. Specifically, the estimated spectrum S2′ corresponds to a primary spectrum of the reflected light from the second measurement point MP2, on an assumption that the second measurement point MP2 is located on the first structural element R1 (for example, a device) of the substrate W. Depending on the arrangement of the first measurement point MP1, the second measurement point MP2, and the third measurement point MP3, the processing system 49 may generate the estimated spectrum S2′ from the primary spectra S1 and S3 by extrapolation. The processing system 49 determines a film thickness from the estimated spectrum S2′ generated. The determination of the film thickness is carried out according to the processes described with reference to FIG. 7. The primary spectra S1 and S3 and the estimated spectra S2′ are stored in the memory 49a of the processing system 49.

The estimated spectrum S2′ is a primary spectrum that is assumed to accurately reflect the film thickness of the substrate W. Therefore, the optical film-thickness measuring device 40 can determine, from the estimated spectrum S2′, an accurate film thickness at the second structural element R2 that is different in structure from the first structural element R1 of the substrate W. In particular, the optical film-thickness measuring device 40 can determine accurate film thicknesses at all of the measurement points MP shown in FIG. 8.

In the present embodiment, for the sake of simplification of descriptions, an estimated spectrum at one measurement point is generated from primary spectra at two measurement points, but the present invention is not limited to the present embodiment. An estimated spectrum at one measurement point may be generated from primary spectra at three or more measurement points. Depending on the surface structure of the substrate, the spectrum of the reflected light from the scribe line may be preferentially used to determine the film thickness. In such a case, the spectrum of the reflected light from the scribe line is classified into the primary spectrum belonging to the first group.

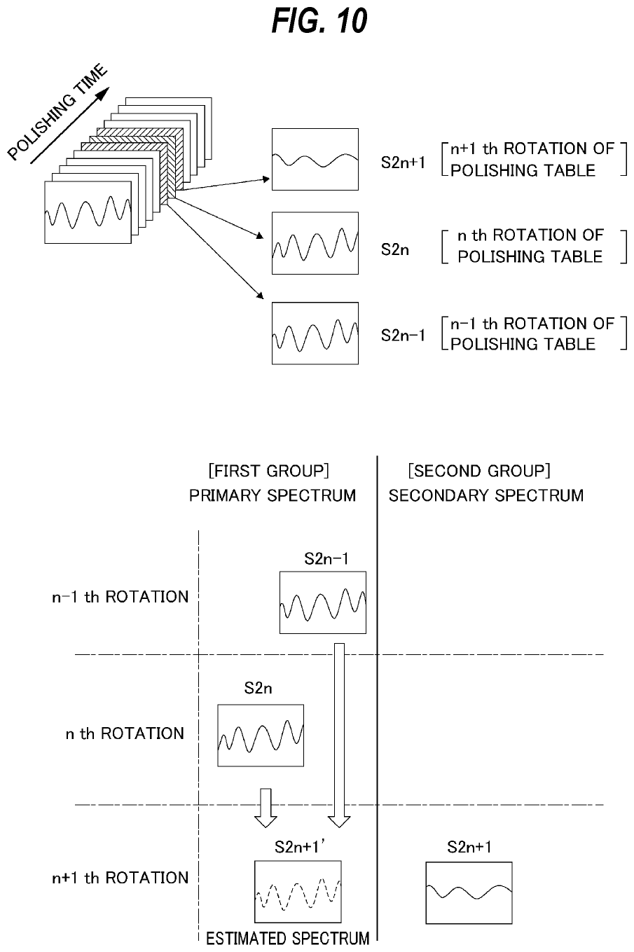

In the embodiment shown in FIG. 9, the processing system 49 uses the primary spectra of the reflected lights from the first measurement point MP1 and the third measurement point MP3 located near the second measurement point MP2 to generate the estimated spectrum S2′ at the second measurement point MP2. In one embodiment, the processing system 49 may generate an estimated spectrum at the second measurement point MP2 from time-series primary spectra at the second measurement point MP2. The time-series primary spectra are spectra arranged along the polishing time. Hereinafter, this embodiment will be described with reference to FIG. 10.

The processing system 49 generates a spectrum of reflected light from the second measurement point MP2 each time the polishing table 3 makes one rotation during polishing of the substrate W to obtain spectra at the second measurement point MP2. The processing system 49 arranges these spectra according to the polishing time (i.e., according to the number of rotations of the polishing table 3), and classifies these spectra based on their shapes into primary spectra belonging to the first group and a secondary spectrum belonging to the second group. In the example shown in FIG. 10, a spectrum S2n−1 generated during a n−1-th rotation of the polishing table 3 is classified into the primary spectrum, and a spectrum S2n generated during a n-th rotation of the polishing table 3 is classified into the primary spectrum, and a spectrum S2n+1 generated during a n+1-th rotation of the polishing table 3 is classified into the secondary spectrum.

The processing system 49 generates, from the primary spectra S2n−1 and S2n, an estimated spectrum S2n+1′ that is expected to be generated during the n+1-th rotation of the polishing table 3. The estimated spectrum S2n+1′ is a primary spectrum corresponding to the secondary spectrum S2n+1 and belonging to the first group. Specifically, the processing system 49 generates the estimated spectrum S2n+1′ by extrapolation using the primary spectrum S2n−1 and the primary spectrum S2n. The processing system 49 determines a film thickness from the estimated spectrum S2n+1′ generated. The determination of the film thickness is carried out according to the processes described with reference to FIG. 7. The primary spectra S2n−1, S2n and the estimated spectra S2n+1′ are stored in the memory 49a of the processing system 49.

The processing system 49 may generate an estimated spectrum by interpolation using a plurality of primary spectra. For example, when the spectra S2n−1 and S2n+1 are classified into the primary spectra and the spectrum S2n is classified into the secondary spectrum, the processing system 49 may generate an estimated spectrum S2n′ by interpolation using the primary spectra S2n−1, S2n+1. This estimated spectrum S2n′ corresponds to the secondary spectrum S2n and belongs to the first group. An estimated spectrum may be generated by interpolation or extrapolation from three or more time-series primary spectra.

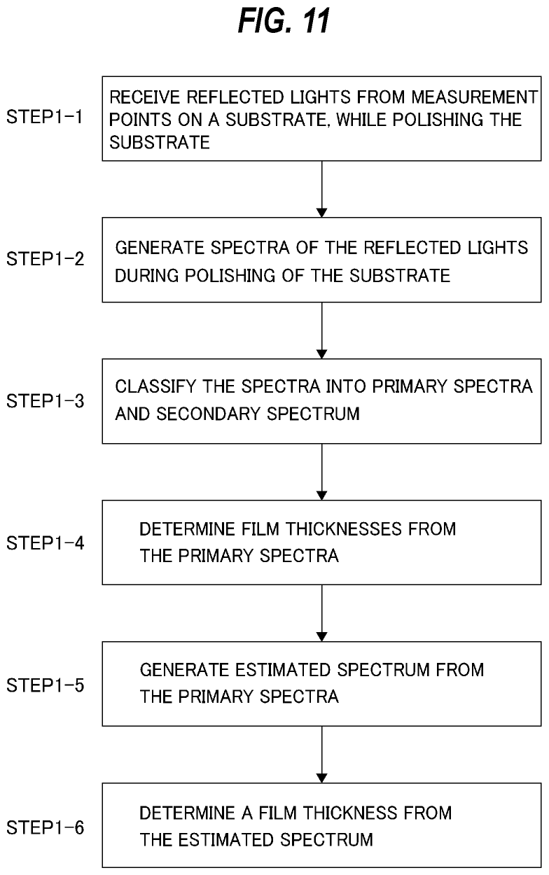

FIG. 11 is a flowchart illustrating operations of the optical film-thickness measuring device 40 when determining a film thickness of the substrate W.

In step 1-1, during polishing of the substrate W, each time the optical sensor head 7 moves across the substrate W (i.e., each time the polishing table 3 makes one rotation), the optical sensor head 7 emits the light to multiple measurement points on the substrate W and receives the reflected lights from these measurement points.

In step 1-2, during polishing of the substrate W, the processing system 49 generates spectra of the reflected lights from the multiple measurement points. The generated spectra are stored in the memory 49a of the processing system 49.

In step 1-3, the processing system 49 classifies the spectra of the reflected lights based on the shape of each spectrum into the primary spectra belonging to the first group and the secondary spectrum belonging to the second group.

In step 1-4, the processing system 49 determines film thicknesses of the substrate W from the primary spectra belonging to the first group.

In step 1-5, the processing system 49 uses the primary spectra to generate an estimated spectrum. This estimated spectrum is a primary spectrum that corresponds to the secondary spectrum classified in the step 1-3 and belongs to the first group. The estimated spectrum is generated according to the processes described with reference to FIG. 9 or FIG. 10.

In step 1-6, the processing system 49 determines a film thickness of the substrate W from the estimated spectrum.

The above step 1-4 may be carried out after the step 1-5. Specifically, the processing system 49 may generate an estimated spectrum in step 1-5 and then determine film thicknesses of the substrate W from the primary spectra and the estimated spectrum.

The processing system 49 sends the determined film thicknesses of the substrate W to the polishing controller 9 shown in FIGS. 1 and 4. The polishing controller 9 controls the operation of polishing the substrate W based on the film thicknesses of the substrate W. For example, the polishing controller 9 may determine a polishing end point at which the film thickness of the substrate W reaches a target film thickness, or may change the polishing conditions for the substrate W when the film thickness of the substrate W reaches a predetermined value.

The processing system 49 may further calculate a moving average of the film thicknesses determined from the primary spectra and the estimated spectrum. The polishing controller 9 may determine the polishing end point or change the polishing conditions based on the moving average of the film thicknesses. The moving average of the film thicknesses may be a temporal moving average of time-series film thicknesses along the time axis, or may be a spatial moving average of film thicknesses at adjacent measurement points. Each of the above-described embodiments can achieve a less variation in both the temporal time-series film thicknesses along the time axis and the spatial film thicknesses at adjacent measurement points. Therefore, the value of the moving average of these film thicknesses indicates an accurate representative value of these film thicknesses.

In one embodiment, the processing system 49 may generate an estimated spectrum from the primary spectra using a spectrum generating model, instead of using the interpolation or the extrapolation. In the example shown in FIG. 9, the processing system 49 inputs the primary spectra S1 and S3 of the reflected lights from the first measurement point MP1 and the third measurement point MP3 into the spectrum generating model, and outputs the estimated spectrum S2′ at the second measurement point MP2 from the spectrum generating model. In the example shown in FIG. 10, the processing system 49 inputs the primary spectrum S2n−1 generated during the n−1-th rotation of the polishing table 3 and the primary spectrum S2n generated during the n-th rotation of the polishing table 3 into the spectrum generating model, and outputs the estimated spectrum S2n+1′ from the spectrum generating model.

The spectrum generating model is a trained model constituted by a neural network that has learned the generation of a primary spectrum according to an artificial intelligence algorithm. Examples of the artificial intelligence algorithm include a support vector regression method, a deep learning method, a random forest method, a decision tree method, and the like. In this embodiment, the deep learning method, which is an example of machine learning, is used. The deep learning method is a learning method based on a neural network having multiple intermediate layers (also called hidden layers). In this specification, machine learning using a neural network having an input layer, two or more intermediate layers, and an output layer is referred to as deep learning.

The spectrum generating model is stored in the memory 49a of the processing system 49. The processing system 49 constructs the spectrum generating model by performing the machine learning using training data according to instructions included in the program electrically stored in the memory 49a. The training data used for the machine learning includes multiple primary spectra generated during polishing of a plurality of substrates having the same multilayered structure as that of the substrate W to be polished. More specifically, the training data includes an objective variable (correct label data) which is one of the multiple primary spectra generated during polishing of the plurality of substrates, and includes explanatory variables which are other primary spectra generated during polishing of the plurality of substrates.

In the example shown in FIG. 9, the explanatory variables may be primary spectra at the first measurement points MP1 and the third measurement point MP3 generated when a certain substrate is polished, and the objective variable may be a primary spectrum at the second measurement point MP2 generated when that substrate is polished. Alternatively, the explanatory variables may be primary spectra at the first measurement point MP1 and the third measurement point MP3 generated when a first substrate is polished, and the objective variable may be a primary spectrum at the second measurement point MP2 generated when a second substrate is polished.

In the example shown in FIG. 10, the explanatory variables may be primary spectra at a predetermined measurement point generated when a first substrate and a second substrate are polished, and the objective variable may be a primary spectrum at the above-mentioned predetermined measurement point generated when a third substrate is polished. The primary spectra used as the explanatory variables and the objective variable in this example are time-series primary spectra.

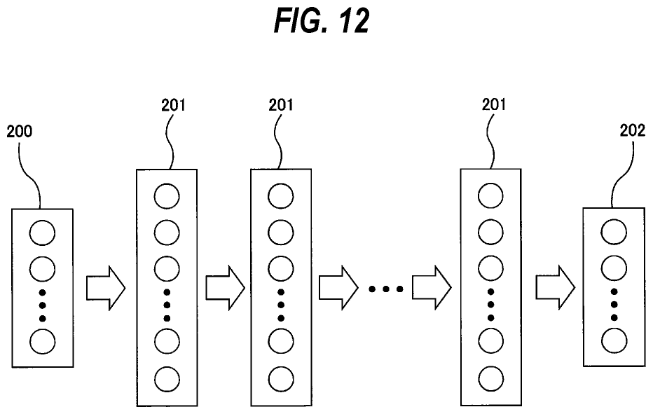

The processing system 49 inputs the primary spectra generated when the substrate W is polished into the spectrum generating model, and outputs the estimated spectrum from the spectrum generating model. FIG. 12 is a schematic diagram showing an example of the spectrum generating model. As shown in FIG. 12, the spectrum generating model is composed of a neural network having an input layer 200, a plurality of intermediate layers 201, and an output layer 202.

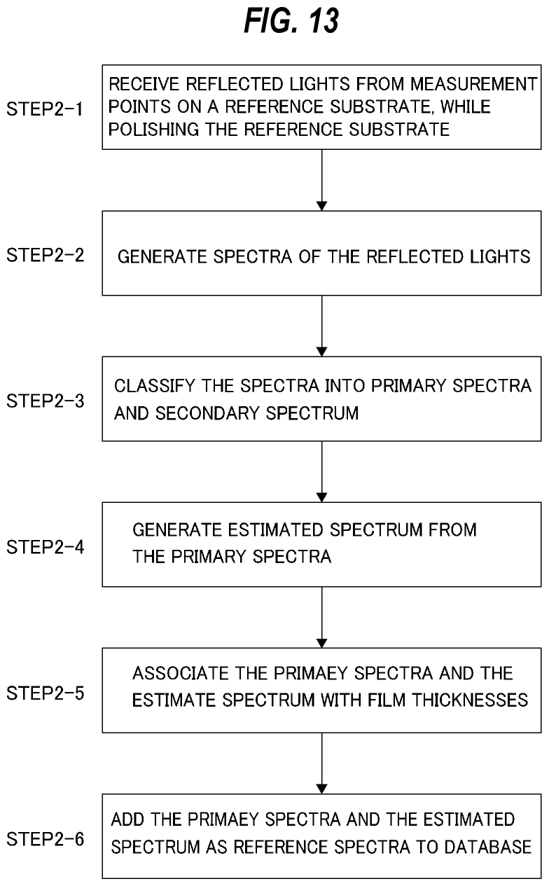

The generation of the estimated spectrum described with reference to FIGS. 9-12 can be used to update the database 60 of the reference spectra shown in FIG. 7. Hereinafter, an embodiment of updating the database 60 of the reference spectra will be described with reference to a flowchart shown in FIG. 13.

In step 2-1, the optical sensor head 7 irradiates multiple measurement points on a reference substrate with light and receives reflected lights from the multiple measurement points on the reference substrate, while the polishing apparatus is polishing the reference substrate having the same multilayered structure as that of the substrate W which is a target substrate. More specifically, each time the optical sensor head 7 moves across the reference substrate (i.e., each time the polishing table 3 makes one rotation), the optical sensor head 7 directs the light to the multiple measurement points on the reference substrate and receives the reflected lights from these measurement points.

In step 2-2, the processing system 49 generates spectra of the reflected lights from the multiple measurement points on the reference substrate. The generated spectra are stored in the memory 49a of the processing system 49.

In step 2-3, the processing system 49 classifies the spectra based on the shape of each spectrum into primary spectra belonging to the first group and a secondary spectrum belonging to the second group.

In step 2-4, the processing system 49 generates an estimated spectrum from the primary spectra. This estimated spectrum corresponds to the secondary spectrum classified in the step 2-3 and belongs to the first group. The estimated spectrum is generated according to the processes described with reference to FIG. 9 or FIG. 10 or FIG. 12.

In step 2-5, the processing system 49 associates the primary spectra and the estimated spectrum with film thicknesses at the multiple measurement points, respectively. A measurement point corresponding to the estimated spectrum is a measurement point at which the light, represented by the secondary spectrum classified in the step 2-3, was reflected.

In step 2-6, the processing system 49 adds the primary spectra and the estimated spectrum as reference spectra to the database 60, thereby updating the database 60. More specifically, the primary spectra and the estimated spectrum, associated with corresponding film thicknesses, are added to the database 60.

Since the substrate W which is an object to be polished and the reference substrate have the same multilayered structure, the primary spectra and the estimated spectrum generated during polishing of the substrate W can also be added as reference spectra to the database 60. The primary spectra and the estimated spectrum generated during polishing of the substrate W can be used as reference spectra for determining a film thickness of other substrates having the same multilayered structure.

In each of the above-described embodiments, the estimated spectrum is generated from a plurality of primary spectra. In one embodiment, the processing system 49 may determine a film thickness at a measurement point corresponding to the secondary spectrum by interpolation or extrapolation using film thicknesses determined from primary spectra, without generating the estimated spectrum. In the example shown in FIG. 9, the processing system 49 calculates a film thickness at the second measurement point MP2 by interpolation or extrapolation using a film thickness determined from the primary spectrum S1 at the first measurement point MP1 and a film thickness determined from the primary spectrum S3 at the third measurement point MP3. In the example shown in FIG. 10, the processing system 49 calculates a film thickness at a predetermined measurement point at a certain point in time by interpolation or extrapolation using film thicknesses at the predetermined measurement point at different points in time. This embodiment, which does not generate an estimated spectrum, can reduce the load on the processing system 49.

Next, a classification method for classifying spectra into a primary spectrum and a secondary spectrum based on the shape of each spectrum will be described. This classification method includes automatic classification of training spectra, producing a classification model, and inputting spectra of reflected lights generated during polishing of a substrate into the classification model.

In the automatic classification of spectra, the training spectra that have been prepared in advance are classified into clusters (or groups) according to a classification algorithm (clustering algorithm), and these clusters (or groups) are further classified into the first group and the second group. Examples of the classification algorithm (clustering algorithm) include a k-means clustering and a Gaussian Mixture Model (GMM). The training spectra prepared in advance are spectra of reflected lights obtained when a plurality of sample substrates are polished. These training spectra are stored in the memory 49a.

Producing the classification model is a process of constructing the classification model by machine learning using the training spectra that have been classified into the first group and the second group and the classification results of these training spectra. The classification model is constituted by a neural network. Constructing the classification model involves determining parameters of the classification model (such as weighting factors and biases).

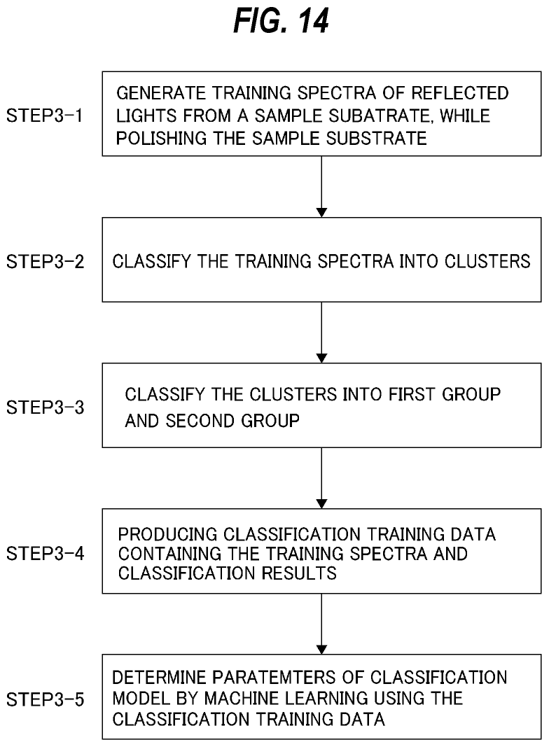

FIG. 14 is a flowchart for explaining the automatic classification of the training spectra and producing of the classification model that constitute the method for classifying spectra.

In step 3-1, while a sample substrate is polished by the polishing apparatus, the processing system 49 receives the intensity measurement data of the reflected light from the sample substrate and generates training spectra from the intensity measurement data. The sample substrate may or may not have the same multilayered structure as the substrate W which is an object to be polished. A plurality of sample substrates are prepared, so that polishing of each sample substrate and generating of training spectra are repeated. The training spectra are stored in the memory 49a.

In step 3-2, the processing system 49 classifies the training spectra into clusters (groups) according to the classification algorithm. As described above, the classification algorithm may be a known clustering algorithm, such as k-means clustering or Gaussian Mixture Model (GMM).

In step 3-3, the processing system 49 further classifies the clusters (groups) into the first group and the second group. The training spectra may be classified into three or more clusters according to the classification algorithm. In that case, at least one of these clusters is classified into (or selected as) the first group, and at least one of the other clusters is classified into (or selected as) the second group. For example, when the training spectra are classified into three clusters, one cluster may be classified into (or selected as) the first group and the other two clusters may be classified into (or selected as) the second group.

The processing system 49 or a user may predetermine which of the clusters (which have been classified according to the classification algorithm) is to be selected as the first group. For example, the processing system 49 classifies the spectra into clusters according to the classification algorithm, selects a cluster to which the largest number of spectra belong as the first group, and designates spectra belonging to the selected first group as the primary spectra. In another example, the processing system 49 selects, as the first group, a cluster to which spectra having film thickness profiles that best match a film thickness profile acquired by an external film-thickness measuring device belong, and designates the spectra belonging to the selected first group as the primary spectra. In still another embodiment, the processing system 49 may produce a virtual model of a multilayered structure of the substrate W to be polished, perform a simulation of light reflection, generate a virtual spectrum (or a theoretical spectrum) of reflected light from the virtual model, determine a cluster to which spectra having shapes close to the virtual spectrum belong, select the determined cluster as the first group, and designate the spectra belonging to the selected first group as the primary spectra. In still another embodiment, the processing system 49 may select, as the first group, a cluster having the smallest variation in spectral shape and designate spectra belonging to the selected first group as the primary spectra.

In step 3-4, the processing system 49 produces the classification training data which includes the training spectra classified into the first group and the second group and the classification results thereof. The classification training data includes the training spectra as explanatory variables, and includes the classification results of each of these training spectra as objective variables. For example, a training spectrum (explanatory variable) classified into the first group is combined with a numerical value (objective variable) indicating the first group as the classification result. Similarly, a training spectrum (explanatory variable) classified into the second group is combined with a numerical value (objective variable) indicating the second group as the classification result. The classification training data is stored in the memory 49a of the processing system 49.

In step 3-5, the processing system 49 determines the parameters (e.g., weighting coefficients, biases, etc.) of the classification model by the machine learning using the above classification training data.

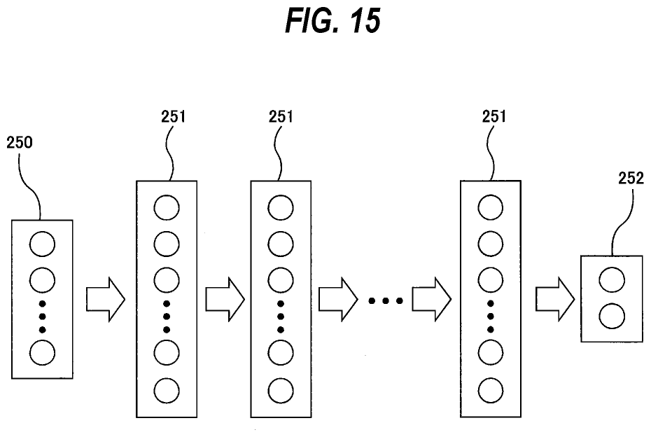

FIG. 15 is a schematic diagram showing an example of the classification model. As shown in FIG. 15, the classification model is constituted by a neural network having an input layer 250, a plurality of intermediate layers 251 and an output layer 252. In one embodiment, deep learning is used as the machine learning algorithm for constructing the classification model. The processing system 49 inputs the training spectrum into the input layer 250 of the classification model. Specifically, the processing system 49 inputs the intensities (each of which may be relative reflectance) of the reflected light at respective wavelengths constituting the training spectrum into the input layer 250 of the classification model.

The processing system 49 adjusts the parameters (e.g., weighting coefficients and biases, etc.) of the classification model so that the classification result (the numerical value indicating the first group or the second group) corresponding to the inputted training spectrum is output from the output layer 252. As a result of such machine learning, the classification model is constructed as a trained model. The classification model is stored in the memory 49a of the processing system 49.

The processing system 49 having the classification model inputs spectra of the reflected lights from the substrate W into the classification model one by one during polishing of the substrate W, and outputs the classification results from the classification model. The processing system 49 classifies the spectra of the reflected lights into the primary spectra belonging to the first group and the secondary spectrum belonging to the second group according to the classification results output from the classification model. The processing system 49 determines film thicknesses of the substrate W using the primary spectra belonging to the first group, and generates the estimated spectrum described above. The processing system 49 determines a film thickness of the substrate W from the estimated spectrum.

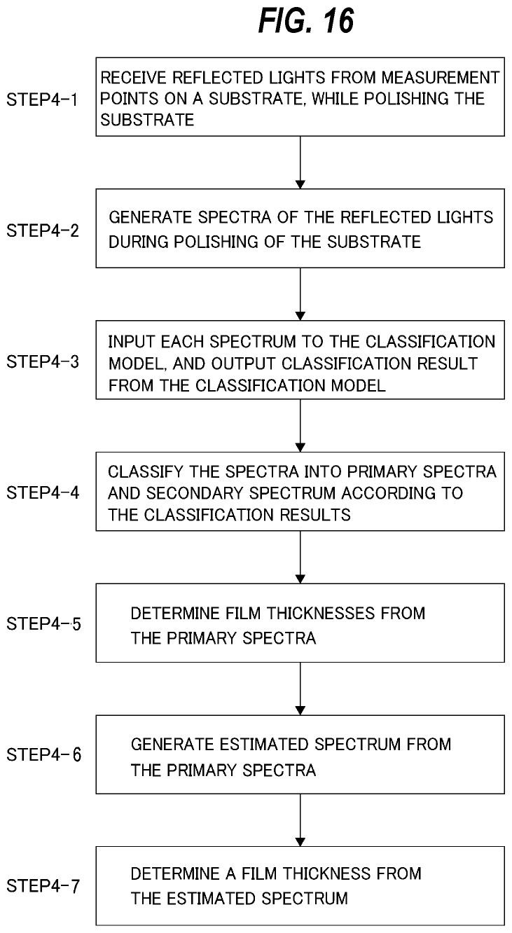

FIG. 16 is a flowchart illustrating operations of the optical film-thickness measuring device 40 having the classification model when determining the film thickness of the substrate W.

In step 4-1 during polishing of the substrate W, each time the optical sensor head 7 moves across the substrate W (i.e., each time the polishing table 3 makes one rotation), the optical sensor head 7 directs the light to the multiple measurement points on the substrate W, and receives the reflected lights from these multiple measurement points.

In step 4-2, during polishing of the substrate W, the processing system 49 generates spectra of the reflected lights from the multiple measurement points. The generated spectra are stored in the memory 49a of the processing system 49.

In step 4-3, the processing system 49 inputs the spectra one by one into the classification model, and performs arithmetic operations according to the calculation algorithm defined by the classification model to output the classification results from the classification model.

In step 4-4, the processing system 49 classifies the spectra of the reflected lights into the primary spectra belonging to the first group and the secondary spectrum belonging to the second group according to the classification results output from the classification model.

In step 4-5, the processing system 49 determines film thicknesses of the substrate W from the primary spectra belonging to the first group.

In step 4-6, the processing system 49 generates, from the primary spectra, an estimated spectrum corresponding to the secondary spectrum and belonging to the first group. The estimated spectrum is generated according to the embodiment described with reference to FIG. 9, FIG. 10, or FIG. 12.

In step 4-7, the processing system 49 determines a film thickness of the substrate W from the estimated spectrum.

The above step 4-5 may be carried out after the above step 4-6. Specifically, the processing system 49 may determine film thicknesses of the substrate W from the primary spectra and the estimated spectrum after generating the estimated spectrum in step 4-6.

Instead of the steps 4-6 and 4-7, the processing system 49 may determine a film thicknesses at a measurement point corresponding to the secondary spectrum by interpolation or extrapolation using the film thicknesses determined from the primary spectra.

The processing system 49 may further calculate a moving average of the film thicknesses that have been determined as described above. Further, the polishing controller 9 may determine a polishing end point or may change the polishing conditions based on the moving average of the film thicknesses. The moving average of the film thicknesses may be a temporal moving average of time-series film thicknesses along the time axis, or may be a spatial moving average of the film thicknesses at adjacent measurement points. Each of the above-described embodiments can achieve a less variation in both the temporal time-series film thicknesses along the time axis and the spatial film thicknesses at adjacent measurement points. Therefore, the value of the moving average of these film thicknesses indicates an accurate representative value of these film thicknesses.

The processing system 49, constituted by at least one computer, operates according to the instructions contained in the program electrically stored in the memory 49a. Specifically, the processing system 49 performs each operation step in each of the above-described embodiments according to the instructions included in the program. The program for causing the processing system 49 to execute these steps is stored in a computer-readable storage medium which is a non-transitory tangible medium, and is provided to the processing system 49 via the storage medium. Alternatively, the program may be input to the processing system 49 via a communication network, such as the Internet or a local area network.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A polishing method comprising:
generating spectra of reflected lights from measurement points on a substrate while polishing the substrate;
classifying the spectra based on a shape of each spectrum into primary spectra belonging to a first group and a secondary spectrum belonging to a second group;
determining film thicknesses of the substrate from the primary spectra; and
determining a film thickness at a measurement point corresponding to the secondary spectrum using the primary spectra or the film thicknesses.

2. The polishing method according to claim 1, wherein determining the film thickness at the measurement point corresponding to the secondary spectrum comprises:
generating an estimated spectrum that corresponds to the secondary spectrum and belongs to the first group; and
determining the film thickness of the substrate from the estimated spectrum.

3. The polishing method according to claim 2, wherein generating the estimated spectrum comprises generating the estimated spectrum by interpolation or extrapolation using the primary spectra.

4. The polishing method according to claim 2, wherein generating the estimated spectrum comprises inputting the primary spectra into a spectrum generating model and outputting the estimated spectrum from the spectrum generating model.

5. The polishing method according to claim 1, wherein determining the film thickness at the measurement point corresponding to the secondary spectrum comprises determining the film thickness at the measurement point corresponding to the secondary spectrum by interpolation or extrapolation using the film thicknesses.

6. The polishing method according to claim 1, wherein classifying the spectra into the primary spectra belonging to the first group and the secondary spectrum belonging to the second group comprises:
inputting each of the spectra generated during polishing of the substrate into a classification model; and
classifying the spectra into the primary spectra belonging to the first group and the secondary spectrum belonging to the second group according to classification results output from the classification model.

7. The polishing method according to claim 6, further comprising:
generating multiple training spectra of reflected lights from a sample substrate while polishing the sample substrate;
classifying the multiple training spectra into the first group and the second group; and
determining parameters of the classification model by machine learning using classification training data including the multiple training spectra and classification results of the multiple training spectra.

8. A polishing method comprising:
generating spectra of reflected lights from measurement points on a reference substrate while polishing the reference substrate;
classifying the spectra based on a shape of each spectrum into primary spectra belonging to a first group and a secondary spectrum belonging to a second group;
generating an estimated spectrum that corresponds to the secondary spectrum and belongs to the first group;
associating the primary spectra and the estimated spectra with film thicknesses;
adding the primary spectra and the estimated spectrum as reference spectra to a database, the database having reference spectra including the primary spectra and the estimated spectrum;
generating a spectrum of reflected light from a substrate, while polishing the substrate;
determining a reference spectrum having the closest shape to the shape of the spectrum of the reflected light from the substrate; and
determining a film thickness associated with the determined reference spectrum.

9. A polishing apparatus comprising:
a polishing table for supporting polishing pad;
a polishing head configured to press a substrate against the polishing pad to polish the substrate;
an optical sensor head configured to emit light to measurement points on the substrate and receive reflected lights from the measurement points; and
a processing system configured to generate spectra of the reflected lights, the processing system being configured to:
classify the spectra based on a shape of each spectrum into primary spectra belonging to a first group and a secondary spectrum belonging to a second group;
determine film thicknesses of the substrate from the primary spectra; and
determine a film thickness at a measurement point corresponding to the secondary spectrum using the primary spectra or the film thicknesses.

10. The polishing apparatus according to claim 9, wherein the processing system is configured to:
generate an estimated spectrum that corresponds to the secondary spectrum and belongs to the first group; and
determine the film thickness of the substrate from the estimated spectrum.

11. The polishing apparatus according to claim 10, wherein the processing system is configured to generate the estimated spectrum by interpolation or extrapolation using the primary spectra.

12. The polishing apparatus according to claim 10, wherein the processing system has a spectrum generating model, and the processing system is configured to input the primary spectra into the spectrum generating model and output the estimated spectrum from the spectrum generating model.

13. The polishing apparatus according to claim 9, wherein the processing system is configured to determine the film thickness at the measurement point corresponding to the secondary spectrum by interpolation or extrapolation using the film thicknesses.

14. The polishing apparatus according to claim 9, wherein the processing system has a classification model, and the processing system is configured to:
input each of the spectra generated during polishing of the substrate into the classification model; and
classify the spectra into the primary spectra belonging to the first group and the secondary spectrum belonging to the second group according to classification results output from the classification model.

15. The polishing apparatus according to claim 14, wherein the processing system has a memory storing multiple training spectra of reflected lights from a sample substrate, and the processing system is configured to:
classify the multiple training spectra into the first group and the second group; and
determine parameters of the classification model by machine learning using classification training data including the multiple training spectra and classification results of the multiple training spectra.

16. A polishing apparatus comprising:
a polishing table for supporting polishing pad;
a polishing head configured to press a substrate against the polishing pad to polish the substrate;
an optical sensor head configured to emit light to measurement points on the substrate and receive reflected lights from the measurement points; and
a processing system having a memory storing a database and spectra of reflected lights from measurement points on a reference substrate, the database containing reference spectra, the processing system being configured to:
classify the spectra of the reflected lights based on a shape of each spectrum into primary spectra belonging to a first group and a secondary spectrum belonging to a second group;
generate an estimated spectrum that corresponds to the secondary spectrum and belongs to the first group;
associate the primary spectra and the estimated spectra with film thicknesses; and
add the primary spectra and the estimated spectrum as reference spectra to the database.
